(19) United States
(12) Patent Application Publication
(10) Pub. No.: US 2015/0136207 A1
(43) Pub. Date: May 21, 2015

(54) ROOF PANEL COMPRISING AN INTEGRATED PHOTOVOLTAIC MODULE

(71) Applicant: Saint-Gobain Glass France, Courbevoie (FR)

(72) Inventors: Jean-Christophe Giron, Edina, MN (US); Harald Stoffel, Alsdorf (DE); Uwe Van Der Meulen, Nideggen (DE); Andreas Nositschka, Aachen (DE); Pascal Remy, Uebach-Palenberg (DE); Marc-Oliver Prast, Herzogenrath (DE); Dirk Neumann, Herzogenrath (DE)

(21) Appl. No.: 14/400,464

(22) PCT Filed: May 17, 2013
(86) PCT No.: PCT/EP2013/060246

§ 371 Date: Nov. 11, 2014

(30) Foreign Application Priority Data
Jun. 5, 2012 (EP) 12170877.0

(51) Int. Cl. H02S 10/40; H01L 31/18; H01L 31/048

(52) U.S. Cl. CPC H02S 10/40; H01L 31/0481; H01L 31/1876
USPC 136/251; 438/66

(57) ABSTRACT

A roof panel with an integrated photovoltaic module is discussed. The roof panel has at least a substrate and an outer pane, which are laminarily bonded to each other via a thermoplastic layer, and embedded in the thermoplastic layer, at least one photovoltaic system that contains at least two strip-shaped solar cells that are connected in series via at least one electrically conductive connecting element.

The invention relates to a roof panel with an integrated photovoltaic module, a method for its production, and use thereof.

It is known that photovoltaic modules can be integrated into the roof panel of vehicles. Such roof panels are known, for example, from DE 3713854 A1, DE 4006756 A1, and DE 4105389 C1.

Conventional roof panels with an integrated photovoltaic module, in particular with a photovoltaic module based on crystalline silicon arranged extensively in the roof panel, are opaque and can have only a slight curvature. This can severely limit the design freedom of the vehicle manufacturer.

The object of the present invention is to provide an improved roof panel with an integrated photovoltaic module. It should be possible to provide a large part of the surface of the roof panel with the photovoltaic module and to provide the roof panel with a strong curvature. In addition, the roof panel should have selectable partial transparency in the region of the integrated photovoltaic module.

The object of the present invention is accomplished according to the invention by a roof panel with an integrated photovoltaic module according to the independent claim 1. Preferred embodiments are given by the subclaims.

The roof panel according to the invention with an integrated photovoltaic module comprises at least the following characteristics:
a substrate and an outer pane, which are laminarily bonded to each other via a thermoplastic layer, and
embedded in the thermoplastic layer, at least one photovoltaic system that contains at least two strip-shaped solar cells that are connected in series by at least one electrically conductive connecting element.

The roof panel according to the invention is provided for the purpose of delimiting the interior, for example, of a motor vehicle from the external surroundings, in the region of the roof. According to the invention, the outer pane is turned toward the external surroundings.

The substrate is turned toward the interior. The solar radiation enters the roof panel via the outer pane and strikes the photovoltaic system inside the thermoplastic layer. The surfaces of the substrate and of the cover pane turned away from each other preferably from the outer surfaces of the roof panel. This means that no further elements, for example, no further panes, are arranged on the surfaces of the substrate facing away from each other and the outer pane. The surfaces of the substrate and the outer pane facing away from each other can, however, have coatings.

The advantage of the invention resides in the division according to the invention of the photovoltaic system into solar cells connected to each other in series. With suitable dimensioning of the individual solar cells, the photovoltaic system as a whole has high flexibility, even when the individual solar cells are only slightly flexible. Thus, roof panels with high curvature can be realized. Moreover, through the dimensioning of the solar cells as well as the surface coverage of the solar cells, a desired partial transparency of the roof panel can be adjusted in the region of the photovoltaic system.

According to the invention, the solar cells are implemented strip-shaped. The term “strip” is understood to mean a shape, preferably a rectangular shape, whose length is clearly greater than its width. According to the invention, the length of the strip is greater than five times its width, preferably greater than ten times its width.

The solar cells preferably have a length from 5 cm to 30 cm, particularly preferably from 10 cm to 20 cm. The solar cells preferably have a width from 1 mm to 10 mm, particularly preferably from 2 mm to 5 mm. This is particularly advantageous with regard to the flexibility of the photovoltaic system, the power of the photovoltaic system, and an anesthetic impression of the roof panel according to the invention.

The strip-shaped solar cells can, for example, be cut from a conventional, commercially available solar cell. As a result of the strip-shaped configuration with the low widths according to the invention, roof panels with curvature can be realized, without being restricted to the use of special, i.e., especially thin solar cells.

The strip-shaped solar cells are preferably arranged parallel to each other such that the long edges of the solar cells are facing each other. Then, the solar cells are advantageously arranged space-savingly and can be connected in series in a simple manner via the electrically conductive connecting elements. The photovoltaic system can also have two or more groups of solar cells arranged next to each other, with, in each case, the solar cells of a group being arranged parallel to each other. Thus, extensive coverage of the roof panel with the photovoltaic system is advantageously obtained.

A photovoltaic system or a group of solar cells arranged parallel to each other according to the invention preferably contains from 10 to 100, particularly preferably from 20 to 50 solar cells. This is particularly advantageous with regard to extensive coverage of the roof panel with the photovoltaic system and the power of the photovoltaic system.

The distance between adjacent solar cells that are arranged parallel to each other is preferably from 1 mm to 10 mm, particularly preferably from 2 mm to 5 mm. The transmittance of light through the roof panel in the region of the photovoltaic system can be adjusted by the distance.

The solar cells are preferably arranged with surface coverage from 20% to 90%, particularly preferably from 50% to 80% in the roof panel in the region of the photovoltaic system. This is particularly advantageous with regard to the power of the photovoltaic system. The transmittance of light through the roof panel in the region of the photovoltaic system can be adjusted by the surface coverage. The region of the photovoltaic system is defined by the outer side edges of the group of solar cells connected to each other in series and contains the solar cells as well as the intermediate spaces between the solar cells. The region of the photovoltaic system is thus the smallest region of the roof panel in which the solar cells of the photovoltaic system are completely arranged.

The photovoltaic system is preferably arranged completely or partially in the see-through region of the roof panel according to the invention. Advantageously, the photovoltaic system can be extensively arranged there and effect a light transmittance level selectable by the manufacturer. The see-through region is the area of the roof panel minus a peripheral edge region with a width of 5 cm. The photovoltaic system is not, or is not exclusively, arranged in the edge region of the roof panel. In a particularly preferred embodiment, the photovoltaic system is arranged completely in the see-through region of the roof panel; thus has a distance from the side edges of the roof panel from the side edges of the roof panel of at least 5 cm.

Each solar cell preferably comprises a photovoltaically active absorber layer between a front electrode and a back electrode. The front electrode is arranged on the surface of the absorber layer facing the outer pane. The back electrode is arranged on the surface of the absorber layer facing the substrate. The front electrode and/or the back electrode can be implemented, for example, as thin conducting or semiconducting layers with thicknesses of preferably from 300 nm to 2 μm. The layers can contain, for example, molybdenum, titanium, tungsten, nickel, titanium, chromium, tantalum, aluminum-doped zinc oxide, and/or indium tin oxide. However, the front electrode and/or the back electrode can also, for example, be implemented as a mesh of thin wires, which contain, for example, aluminum, copper, silver, and/or gold.

In an advantageous embodiment of the invention, the photovoltaically active absorber layer contains crystalline silicon, for example, monocrystalline silicon, or polycrystalline silicon. The photovoltaically active absorber layer preferably has a layer thickness from 10 μm to 500 μm, particularly preferably from 20 μm to 200 μm. Such so-called “thick film solar cells” are, in principle, only slightly bendable. The division according to the invention of the photovoltaic system into solar cells connected in series to each other is particularly advantageous because it can give bendability to the photovoltaic system, which enables realization of roof panels with high curvature.

However, the photovoltaic system can, in principle, also be a thin-film system. This means layer systems with thicknesses of only a few microns. The photovoltaically active absorber layer can contain, for example, amorphous or micromorphous silicon, cadmium telluride (CdTe), cadmium selenide (CdSe), gallium arsenide (GaAs), semiconductive organic polymers or oligomers or a chalcopyrite semiconductor such as a compound of the group copper indium sulfur/selenium (CIS), for example, copper indium diselenide (CuInSe₂), or a compound of the group copper indium gallium sulfur/selenium (CIGS), for example, Cu(InGa)(SSe)₂. The photovoltaically active absorber layer can preferably have a layer thickness from 500 nm to 5 μm, particularly preferably from 1 μm to 3 μm.

Of course, the photovoltaic system can include other individual layers that are known to the person skilled in the art, for example, a buffer layer for adapting the electronic properties between der absorber layer and an electrode layer or diffusion barrier layers.

According to the invention, the solar cells of the photovoltaic system are connected in series to each other via electrically conductive connecting elements. The back electrode of each solar cell is electrically conductively connected to the front electrode of the adjacent solar cell in a first direction. The front electrode of the solar cell is electrically conductively connected to the back electrode of the adjacent solar cell in the other direction. The connection between two adjacent solar cells is made by means of at least one connecting element. The electrically conductive connecting elements are preferably implemented as bands or strips that contain at least one metal or one metal alloy. The electrically conductive connecting elements preferably contain at least aluminum, copper, tinned copper, gold, silver, tin, or alloys or mixtures thereof. The electrically conductive connecting elements preferably have a thickness from 0.03 mm to 0.8 mm. The electrically conductive connecting elements preferably have a width from 0.5 mm to 20 mm, particularly preferably from 2 mm to 8 mm. The term “width” refers to the dimension of the connecting element along which the connecting elements make contact with the electrodes. The length of the connecting element depends on the distance between adjacent solar modules. A particularly advantageous and effective electrical contacting of adjacent solar cells is thus achieved. A stable connection between the connecting element and the electrode can be obtained, for example, by soldering, welding, bonding, clamping, gluing using an electrically conductive adhesive, or by suitable insertion into the thermoplastic intermediate layer.

Collecting conductors known per se, so-called “busbars”, for the electrical contacting of the photovoltaic system are preferably embedded in the thermoplastic layer. The two end solar cells of the series circuit are electrically connected in each case to a busbar preferably directly or, in each case, via at least one electrically conductive connecting element. The busbar is preferably implemented as a band or strip. The busbar preferably contains at least one metal or one metal alloy. In principle, any electrically conductive material that can be processed into films can be used for the busbar. Particularly suitable materials for the busbar are, for example, aluminum, copper, tinned copper, gold, silver, or tin and alloys thereof. The busbar has, for example, a thickness from 0.03 mm to 0.3 mm and a width from 2 mm to 16 mm.

The external leads of the photovoltaic system are preferably implemented as suitable cables, preferably flat conductors such as foil conductors. The cables are connected to the busbars, preferably by gluing, soldering, welding, clamping, bonding, or gluing. The cables preferably extend starting from the busbars in the interior of the thermoplastic layer beyond the side edges of the thermoplastic layer.

In an advantageous embodiment of the invention, the roof panel contains at least two photovoltaic systems according to the invention, which are connected in parallel by contacting to at least two common busbars. The roof panel can include, for example, from 2 to 15, preferably from 3 to 8 photovoltaic systems.

In an advantageous embodiment of the invention, the substrate contains glass, preferably flat glass, float glass, quartz glass, borosilicate glass, or soda lime glass. The substrate can be non-prestressed, partially prestressed, prestressed, or cured, for example, thermally or chemically cured. However, the substrate can also contain plastics, for example, rigid plastics, in particular polyethylene, polypropylene, polycarbonate, polymethyl methacrylate, polystyrene, polyamide, polyester, polyvinyl chloride, and/or mixtures thereof. The thickness of the substrate is preferably from 0.7 mm to 25 mm, particularly preferably from 0.8 mm to 5 mm. The particular advantage resides in the stability of the roof panel according to the invention.

In another advantageous embodiment of the invention, the substrate is implemented as a flexible film. The thickness of the flexible film is preferably greater than or equal to 0.02 mm, for example, from 0.02 mm to 2 mm. The thickness of the flexible film is particularly preferably from 0.25 mm to 2 mm, most particularly preferably from 0.3 mm to 1.5 mm, and in particular from 0.45 mm to 1 mm. The particular advantage resides in a low weight of the roof panel according to the invention and low production costs. The flexible film preferably contains at least one polymer, particularly preferably a thermoplastic polymer. The thermoplastic polymer is preferably substituted with fluorine. This is particularly advantageous with regard to the chemical and mechanical stability of the substrate. The substrate most particularly preferably contains at least polyvinyl fluoride, and/or polyvinylidene fluoride. This is particularly advantageous with regard to the chemical and mechanical resistance as well as the adhesion of the thermoplastic layer on the substrate. However, the flexible film can also be made of other materials, for example, of suitable metals or alloys.

The outer pane preferably contains glass, preferably flat glass, float glass, quartz glass, borosilicate glass, or soda lime glass. The outer pane can be non-prestressed, partially prestressed, prestressed, or cured, for example, thermally or chemically cured. The thickness of the outer pane is preferably from 1.0 mm to 12 mm, particularly preferably from 1.4 mm to 4 mm. This is particularly advantageous with regard to the stability of the roof panel according to the invention and the protection of the photovoltaic layer system against external influences, for example, against damage from precipitation such as hail or sleet. When the substrate is implemented as a flexible film, the thickness of the outer pane is preferably from 2.8 mm to 5 mm. Advantageous stability of the roof panel is thus achieved. However, the outer pane can, in principle, also contain plastics, for example, rigid plastics, in particular polyethylene, polypropylene, polycarbonate, polymethyl methacrylate, polystyrene, polyamide, polyester, polyvinyl chloride, and/or mixtures thereof.

The thermoplastic layer preferably contains at least one thermoplastic polymer, preferably ethylene vinyl acetate (EVA), polyvinyl butyral (PVB), polyurethane (PU), polyethylene (PE), and/or polyethylene terephthalate (PET). However, the thermoplastic layer can also contain, for example, at least polypropylene, polycarbonate, polymethyl methacrylate, polyacrylate, polyvinyl chloride, polyacetate resin, casting resins, acrylates, fluorinated ethylene propylene, polyvinyl fluoride, and/or ethylene tetrafluoroethylene. The thickness of the thermoplastic layer is preferably from 0.5 mm to 10 mm, particularly preferably from 1 mm to 5 mm and most particularly preferably from 2 mm to 4 mm. The thermoplastic layer wird preferably formed from at least two thermoplastic films, between which the photovoltaic system is arranged. Each thermoplastic film preferably has a thickness from 0.25 mm to 1 mm, for example, 0.38 mm or 0.76 mm.

The roof panel according to the invention can have any three-dimensional shape. The roof panel can be planar or slightly or greatly curved in one or a plurality of spatial directions. The radii of curvature of the curved roof panel can be, for example, from 50 mm to 1100 mm. The radius of curvature does not have to be constant over the entire roof panel. There can be greatly and less greatly curved regions. There can even be planar and curved regions. In conventional roof panels with an integrated photovoltaic module, radii of curvature from 700 mm to 1000 mm typically occur. In contrast, by means of the configuration of the photovoltaic system according to the invention, roof panels that have radii of curvature less than or equal to 800 mm, preferably less than or equal to 650 mm at least in one region, can be realized.

The area of the roof panel according to the invention can vary widely and thus be ideally adapted to the requirements in the individual case. The area of the roof panel can be, for example, from 100 cm² all the way to 5 m², preferably from 0.5 m² to 2.5 m².

The area of the photovoltaic system according to the invention or the plurality of photovoltaic systems according to the invention is preferably from 20% to 100% of the area of the roof panel according to the invention. This is particularly advantageous with regard to the power of the integrated photovoltaic module and the transmittance of visible light through the roof panel as well as an aesthetic appearance of the roof panel. The area of the photovoltaic system can be, for example, from 0.3 m² to 3 m², preferably 0.5 m² to 2 m².

The roof panel according to the invention preferably has a total transmittance of visible light from 20% to 50%. The term total transmittance refers to the fraction of all the light striking the roof panel that passes through the pane. In the range indicated for total transmittance, on the one hand, an agreeable level of brightness is obtained in the interior, and, on the other, excessive heating of the interior as a result of direct sunlight is avoided. The total transmittance can be adjusted, in particular, by the dimensioning of the solar cells according to the invention and by the surface coverage of the solar cells as well as by the fraction of the area of the roof panel provided with the photovoltaic system. A further reduction in the transmittance can be obtained, for example, by a tinted substrate.

The integrated photovoltaic module has, in a preferred embodiment, a specific maximum attainable power P_{MPP} from 10 W/m² to 300 W/m², particularly preferably from 50 W/m² to 150 W/m². The power is measured under the usual standard test conditions for photovoltaic modules (irradiance of 1000 W/m², temperature 25° C., radiation spectrum AM 1.5 global).

The object of the invention is further accomplished by a method for producing a roof panel with an integrated photovoltaic module, wherein at least

(a) at least two strip-shaped solar cells are inserted into a thermoplastic layer and are connected in series via at least one electrically conductive connecting element, wherein a photovoltaic system is created,

(b) the thermoplastic layer is laminarily arranged between a substrate and an outer pane, and

(c) the substrate is bonded to the outer pane via the thermoplastic layer under the action of heat, vacuum, and/or pressure.

The thermoplastic layer is preferably formed from at least a first and a second thermoplastic film, with the photovoltaic system laminarily inserted between the first and the second thermoplastic film. Each thermoplastic film preferably has a thickness from 0.25 mm to 1 mm, particularly preferably from 0.5 mm to 0.8 mm. The first and the second thermoplastic film can be made from the same material or from different materials. The thermoplastic layer can, of course, be formed from more than two thermoplastic films.

In one embodiment of the method according to the invention, the substrate or the outer pane is prepared first. At least the first thermoplastic film is arranged on one surface of the substrate or of the outer pane. Then, the solar cells are arranged on the first thermoplastic layer. The solar cells can subsequently be connected in series by means of the electrically conductive connecting element. Alternatively, the solar cells can already be arranged in advance with the electrical connecting elements, for example, on a carrier film, and this carrier film can be arranged on the first thermoplastic film. Subsequently, at least the second thermoplastic film is laminarily arranged on the first thermoplastic film, which is now provided with the photovoltaic system. In process step (b), in this embodiment, the outer pane or the substrate is laminarily arranged on the second thermoplastic layer facing surfaces, by which means the thermoplastic layer with the photovoltaic system is arranged between the substrate and the outer pane.

In an alternative embodiment, the solar cells and the electrically conductive connecting elements are inserted between at least the first and the second thermoplastic film even before one of the thermoplastic films is arranged on the substrate or the cover pane. The first and the second thermoplastic film are preferably bonded under the action of heat, pressure, and/or vacuum to form a pre-laminated thermoplastic layer with an embedded photovoltaic system. In process step (b), the prefabricated pre-laminate is arranged between the substrate and the cover pane.

The advantage of such a pre-laminate resides in simple and economical production of the roof panel according to the invention. The pre-laminate can be prepared before the bonding of the substrate to the outer pane. Then, the conventional methods for producing a roof panel can be used, wherein the thermoplastic intermediate layer, via which the substrate is conventionally glued to the outer pane, is replaced by the pre-laminate. In addition, the photovoltaic system in the interior of the pre-laminate is advantageously protected against damage, in particular, corrosion. Consequently, the pre-laminate can clearly be prepared before the actual production of the roof panel, even in large quantities, which can be desirable for economic reasons. The pre-laminate can be bonded to the substrate and the outer pane directly or via another thermoplastic film.

When busbars are provided for the electrical contacting of the photovoltaic system, in process step (a), the busbars are inserted into the thermoplastic layer and contacted with the photovoltaic system directly or via electrically conductive connecting elements, for example, by welding, bonding, soldering, clamping, or gluing by means of an electrically conductive adhesive or by appropriate insertion. The busbars are preferably connected to foil conductors that extend over the side edges of the thermoplastic layer and serve as external leads.

If the substrate contains glass, the bonding of the substrate to the outer pane is done via the thermoplastic layer using methods known per se for producing a laminated glazing. For example, so-called “autoclave processes” can be performed at a high pressure of roughly 10 bar to 15 bar and temperatures from 130° C. to 145° C. for roughly 2 hours. Vacuum bag or vacuum ring methods known per se operate, for example, at roughly 200 mbar and 130° C. to 145° C.

The outer pane, the thermoplastic layer with the photovoltaic system, and the substrate can also be pressed in a calender between at least one pair of rollers to form a roof panel according to the invention. Systems of this type for producing composite glazings are known and normally have at least one heating tunnel upstream from a pressing unit. The temperature during the pressing procedure is, for example, from 40° C. to 150° C. Combinations of calendering and autoclaving methods have proved particularly valuable in practice.

Alternatively, vacuum laminators can be used. These consist of one or a plurality of heatable and evacuable chambers in which the outer pane and substrate can be laminated within, for example, roughly 60 minutes at reduced pressures of 0.01 mbar to 800 mbar and temperatures of 80° C. to 170° C.

If the substrate is configured as a flexible film, the bonding of the substrate to the outer pane is done in a particularly advantageous embodiment in the manner described in the following.

Before process step (c), a separating film is arranged on the surface of the substrate facing away from the outer pane and a support pane is arranged on the surface of the separating film facing away from the substrate. The support pane is preferably a rigid pane and preferably contains glass, particularly preferably flat glass, float glass, quartz glass, borosilicate glass, or soda lime glass or plastics, preferably polyethylene, polypropylene, polycarbonate, polymethyl methacrylate, polystyrene, polyamide, polyester, polyvinyl chloride, and/or mixtures thereof. The thickness of the support pane is preferably from 1.0 mm to 25 mm, particularly preferably from 1.4 mm to 5 mm. The surface of the support pane facing the substrate should have the same curvature as the surface of the outer pane facing the substrate. The support pane is thus selected in terms of size and shape such that it would, in principle, be suitable to be bonded to the outer pane to form a composite pane. The separating film is produced from a material that is suitable for preventing durable adhesion between the support pane and the substrate. The separating film preferably contains at least one polytetrahalogen ethylene, particularly preferably at least polytetrafluoroethylene and/or polychlorotrifluoroethylene. This is particularly advantageous with regard to the adhesion-impeding properties of the separating film. The separating film preferably has a thickness from 0.01 mm to 10 mm, particularly preferably from 0.1 mm to 2.5 mm, for example, from 0.1 mm to 1 mm.

The stack made up of the outer pane, thermoplastic layer with a photovoltaic system, substrate, separating film, and support pane can be simply subjected to methods known per se for producing a composite glazing, for example, those described above. Thus, a durably stable bond between the outer pane and substrate is provided via the thermoplastic layer. Due to the adhesion-impeding action of the separating film, the support pane can subsequently be removed in a simple manner.

Another aspect of the invention comprises the use of a roof panel according to the invention in vehicles for travel on land, in the air, or on water, preferably in trains, streetcars, ships, and motor vehicles such as buses, trucks, and, in particular, passenger cars. By means of the electrical energy obtained using the integrated photovoltaic module, the battery of an electric vehicle can, for example, be cooled, the passenger compartment can be cooled while the vehicle is parked, a secondary battery of the vehicle can be charged, or a heatable window can be operated while the vehicle is parked.

The invention is explained in detail with reference to drawings and exemplary embodiments. The drawings are schematic representations and not true to scale. The drawings in no way restrict the invention. They depict:

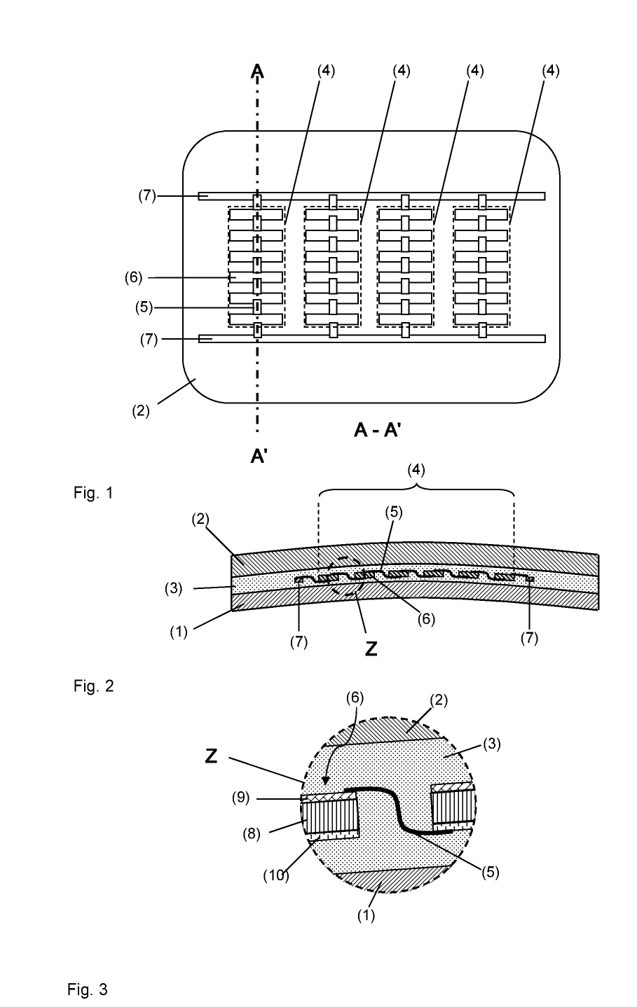

FIG. 1 a plan view of one embodiment of the roof panel according to the invention with an integrated photovoltaic module,

FIG. 2 a cross-section along A-A′ through the roof panel of FIG. 1,

FIG. 3 an enlarged view of the section Z of FIG. 2,

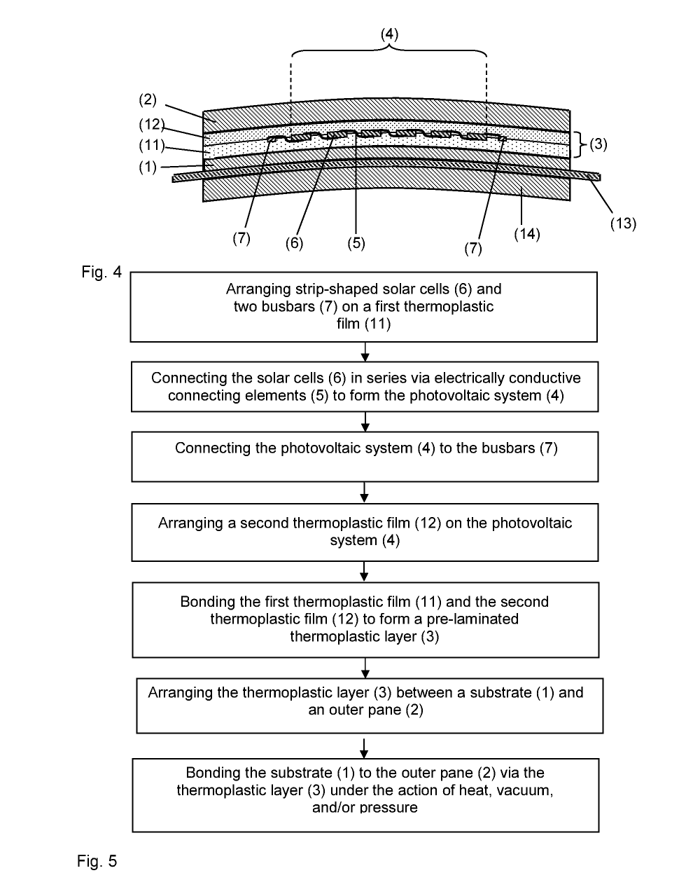

FIG. 4 a cross-section through the substrate, the thermoplastic layer with the photovoltaic system, the outer pane, the separating film, and the support pane before the production of a roof panel according to the invention, and

FIG. 5 an exemplary embodiment of the method according to the invention using a flowchart.

FIG. 1, FIG. 2, and FIG. 3 each depict a detail of a roof panel according to the invention with an integrated photovoltaic module. The roof panel comprises a substrate 1 and an outer pane 2 that are bonded to each other by means of a thermoplastic layer 3. The roof panel is the roof panel of a motor vehicle, wherein the outer pane 2 is intended to face the external surroundings in the installed position. The outer pane 2 is made of thermally prestressed soda lime glass and has a thickness of 2.6 mm. The substrate 1 is made of thermally prestressed soda lime glass and as a thickness of 2.1 mm. The roof panel is formed with a curve, as is usual for motor vehicle roof panels. The roof panel has a width of 110 cm and a length of 140 cm. FIG. 1 depicts a plan view of the outer pane 2 of the roof panel. The photovoltaic system 4 and the busbars 7 can be discerned through the outer pane.

Four photovoltaic systems 4 according to the invention are embedded in the thermoplastic layer 3. The thermoplastic layer 3 contains polyvinyl butyral (PVB) and has a thickness of roughly 3 mm. The thermoplastic layer 3 was formed from four thermoplastic films made of PVB with a thickness of 0.76 mm each. Two of the thermoplastic films were arranged between the photovoltaic system 4 and a substrate 1 during the production of the thermoplastic layer 3. Two other thermoplastic films were arranged between a photovoltaic system 4 and outer pane 2 during the production of the thermoplastic layer 3. The photovoltaic systems 4 are advantageously protected in the interior of the thermoplastic layer 3 against environmental influences, in particular corrosion.

Each photovoltaic system 4 includes a group of strip-shaped solar cells 6. Each solar cell 6 has a length of 15.6 cm and a width of 3 mm. Adjacent solar cells 6 of a photovoltaic system 4 have a distance of 3 mm from each other. The depiction of the solar cells 6 is not true to scale. In particular, the width of the solar cells 6 is depicted greatly enlarged for clarity; the number of solar cells is greatly reduced. Each photovoltaic system 4 includes, for example, 100 solar cells, such that each photovoltaic system 4 has, as a whole, an area of 0.1 m². The surface coverage in the region of the photovoltaic system 4 is roughly 50%. In the context of the invention, the region of a photovoltaic system 4″ is defined by the outermost side edges of the solar cells of the photovoltaic system 4. The region of a photovoltaic system 4 contains solar cells 6 as well as the intermediate spaces between the solar cells 6 and is indicated by the dashed rectangle in FIG. 1.

Each solar cell 6 includes a photovoltaically active absorber layer 8 between a front electrode 9 and a back electrode 10. The absorber layer 8 contains polycrystalline silicon and has a thickness of 0.2 mm. The back electrode 10 contains silver. The front electrode 9 is implemented as a mesh of thin copper wires. Thus, the front electrode 9 is largely transparent to incident light.

Absorber layers 8 based on polycrystalline silicon are only slightly flexible. Nevertheless, due to the division according to the invention of the photovoltaic system 4 into strip-shaped solar cells 6, the photovoltaic system 4 has great flexibility. Thus, even curved roof panels can be realized. In addition, the roof panel is not opaque in the region of the photovoltaic system 4 since light can pass through the roof panel in the intermediate spaces between the solar cells 6. Completely opaque photovoltaic systems 4 would result in a nonuniform and, consequently, non-anesthetic or even annoying entry of light into the vehicle interior. The transmittance of light in the region of the photovoltaic system 4 can be adjusted by the dimensioning of the solar cells 6 as well as the distance between the solar cells 6 (and, thus, by the surface coverage). These are major advantages of the invention.

The solar cells 6 of each photovoltaic system 4 are connected to each other in series via electrically conductive connecting elements 5. For this, the back electrode 10 of a solar cell 6 is placed in contact with the front electrode 9 of the adjacent solar cell 6, whose back electrode 9 is, in turn, placed in contact with the front electrode 9 of the next solar cell 6. The electrically conductive connecting elements 5 are implemented as strips of copper with a thickness of 0.5 mm and a width of 3 mm. Advantageously, by means of the in-series connection of the solar cells 6, high power of the photovoltaic system 4 can be achieved.

The roof panel also contains two busbars 7, which are also embedded in the thermoplastic layer 3. The busbars are configured as strips of copper with a thickness of 0.5 mm, a length of 5 m, and a width of 1 mm. Each of the four photovoltaic systems 4 has two end solar cells 6. One of the end solar cells 6 of each photovoltaic system 4 is connected via an electrically conductive connecting element 5 to the first busbar 7. The other end solar cell 6 of each photovoltaic system 4 is connected via an electrically conductive connecting element 5 to the second busbar 7. The four photovoltaic systems 4 are thus connected in parallel.

In an alternative embodiment, the solar cells 6 can also be arranged, as depicted in the figure, in groups of solar cells 6 parallel to each other, which, for example, are connected in series via their end solar cells 6 by means of the electrically conductive connecting elements 5. In this embodiment, all solar cells 6 would form a single photovoltaic system 4 in the context of the invention.

FIG. 4 depicts a cross-section through the components of an alternative configuration of the roof panel according to the invention before bonding to form the roof panel in a preferred embodiment of the method according to the invention. The substrate 1, a first thermoplastic film 11, the photovoltaic system 4 with the solar cells 6, the electrically conductive connecting elements 5 and the busbars 7, a second thermoplastic film 12 and the outer pane 2 are arranged congruently one over another. The photovoltaic system 4 and the busbars 7 are configured as in FIG. 1. In contrast to the configuration of FIG. 1, the substrate 1 is not made of glass, but, instead, is implemented as a flexible film made of polyvinyl fluoride (DuPont Tedlar©) with a thickness of 0.8 mm. Thus, an advantageously reduced weight of the roof panel is obtained. The outer pane 2 is made of thermally prestressed soda lime glass and has a thickness of 3 mm. The first thermoplastic film 11 and the second thermoplastic film 12 are made of PVB and have a thickness of 0.76 mm. During lamination of the roof panel, the first and the second thermoplastic film 11, 12 form the thermoplastic intermediate layer 3. Alternatively, the first and the second thermoplastic film 11, 12 can already be connected to the embedded photovoltaic system 4 in advance to form a pre-laminated thermoplastic layer 3.

A support pane 14 is arranged on the surface of the substrate 1 facing away from the outer pane 2. The support pane 14 is made of soda lime glass and has the same size and shape as the outer pane 2. A separating film 13 is arranged between the support pane 14 and the substrate 1. The separating film 13 is made of polytetrafluoroethylene and has a thickness of 0.8 mm. The separating film 13 covers the entire surface of the substrate 1. The area of the separating film 13 is thus at least as large as the surface of the substrate 1, but can also be larger, as in the example depicted, and can protrude beyond the side edges of the substrate 1.

Because of the support pane 14, the roof panel according to the invention can be produced in a simple manner although the substrate 1 is implemented as a flexible film. For the bonding of substrate 1 and roof panel 2 via the thermoplastic layer 3, the stack composed of support pane 14, separating film 13, substrate 1, thermoplastic films 11, 12, photovoltaic system 4 with busbars 7, and outer pane 2 can be subjected in a simple manner to methods known per se for producing a composite glazing. Thus, a durably stable bond between the outer pane 2 and the substrate 1 is achieved via the thermoplastic layer 3. The separating film 13 impedes adhesion between the support pane 14 and the substrate 1. After the production of the roof panel, the support pane 14 and the separating film 13 can be removed in a simple manner.

FIG. 5 depicts, by way of example, and embodiment of the method according to the invention for producing a roof panel with an integrated photovoltaic module.

It was unexpected and surprising for the person skilled in the art that, by means of the division according to the invention of the photovoltaic system 4 into solar cells 6 connected in series to each other, a roof panel with an integrated photovoltaic module can be produced, which can also be implemented greatly curved and with which the level of transmittance in the area of the photovoltaic system 4 can be adjusted. Through the connection of the solar cells 6 in series as well as, optionally, through the connection of multiple photovoltaic systems 4 in parallel, high power outputs can also be obtained.

### LIST OF REFERENCE CHARACTERS

(1) substrate
(2) outer pane
(3) thermoplastic layer
(4) photovoltaic system
(5) electrically conductive connecting element
(6) solar cell
(7) busbar
(8) absorber layer
(9) front electrode
(10) back electrode
(11) first thermoplastic film
(12) second thermoplastic film
(13) separating film
(14) support pane
A-A′ section line
Z section of the roof panel

1. A roof panel with an integrated photovoltaic module, comprising at least:
a substrate and an outer pane, which are laminarily bonded to each other via a thermoplastic layer, and
embedded in the thermoplastic layer, at least one photovoltaic system that contains at least two strip-shaped solar cells that are connected in series via at least one electrically conductive connecting element,
wherein the roof panel is curved and wherein the solar cells have a width from 1 mm to 10 mm.

2. The roof panel according to claim 1, wherein each solar cell comprises a photovoltaically active absorber layer between a front electrode and a back electrode and wherein the photovoltaically active absorber layer contains at least monocrystalline or polycrystalline silicon.

3. The roof panel according to claim 1, wherein the solar cells have a length from 5 cm to 30 cm, preferably from 10 cm to 20 cm and a width from 2 mm to 5 mm and are preferably arranged parallel to each other.

4. The roof panel according to claim 1, wherein the photovoltaic system contains from 10 to 100, preferably from 20 to 50 solar cells connected in series.

5. The roof panel according to claim 1, wherein the solar cells are arranged in the region of the photovoltaic system with surface coverage from 20% to 90%.

6. The roof panel according to claim 1, wherein the electrically conductive connecting element contains at least copper, aluminum, gold, silver, tin, or alloys thereof and preferably has a thickness from 0.03 mm to 0.8 mm and a width from 0.5 mm to 20 mm.

7. The roof panel according to claim 1, which contains at least two photovoltaic systems that are connected in parallel by means of at least two busbars.

8. The roof panel according to claim 1, wherein the substrate contains glass, preferably flat glass, float glass, quartz glass, borosilicate glass, or soda lime glass, and preferably has a thickness from 0.7 mm to 25 mm, particularly preferably from 0.8 mm to 5 mm.

9. The roof panel according to claim 1, wherein the substrate is implemented as a flexible film that preferably contains at least one thermoplastic polymer, particularly preferably polyvinyl fluoride and/or polyvinylidene fluoride and preferably has a thickness from 0.25 mm to 2 mm, particularly preferably from 0.3 mm to 1.5 mm, most particularly preferably from 0.45 mm to 1 mm.

10. The roof panel according to claim 1, wherein the thermoplastic layer has a thickness from 0.5 mm to 10 mm, preferably from 1 mm to 5 mm, particularly preferably from 2 mm to 4 mm and preferably contains at least one thermoplastic polymer, particularly preferably ethylene vinyl acetate (EVA), polyvinyl butyral (PVB), polyurethane (PU), polyethylene (PE), and/or polyethylene terephthalate (PET).

11. The roof panel according claim 1, wherein the outer pane contains glass, preferably flat glass, float glass, quartz glass, borosilicate glass, or soda lime glass and preferably has a thickness from 1.0 mm to 12 mm, particularly preferably from 1.4 mm to 4 mm.

12. The roof panel according to claim 1, which has, at least in one region, a radius of curvature less than or equal to 800 mm.

13. A method for producing a roof panel with an integrated photovoltaic module according to claim 1, wherein at least
at least two strip-shaped solar cells are inserted into a thermoplastic layer and are connected in series via at least one electrically conductive connecting element, wherein a photovoltaic system is created,
the thermoplastic layer is laminarily arranged between a substrate and an outer pane, and
the substrate is bonded to the outer pane via the thermoplastic layer under the action of heat, vacuum, and/or pressure.

14. The method according to claim 13, wherein in process step, the photovoltaic system is arranged between at least one first thermoplastic film and one second thermoplastic film, which are subsequently bonded under the action of heat, vacuum, and/or pressure to form a pre-laminated thermoplastic layer.

15. A method comprising:
using the roof panel according to claim 1 in vehicles for travel on land, in the air, or on water, preferably in trains, streetcars, ships, and motor vehicles such as buses, trucks, and, in particular, passenger cars.
